(19) United States
(12) Patent Application Publication
(10) Pub. No.: US 2004/0232560 A1
(43) Pub. Date: Nov. 25, 2004

(54) Flip chip assembly process and substrate used therewith

(76) Inventor: Chao-Yuan Su, Kaohsiung (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/443,418

(22) Filed: May 22, 2003

(51) Int. Cl. H01L 23/48

(52) U.S. Cl. 257/778

(57) ABSTRACT

A flip chip assembly process forming an underfill encapsulant. The process includes providing a substrate having a conductive pad completely or partially exposed on a surface, forming a pre-solder tapering to an upper point over the conductive pad and protruding from the substrate, forming an encapsulant having a silica filler over the substrate, providing a chip having a conductive bump, attaching the chip to the substrate, and reflowing the pre-solder to integrally attach the conductive bump and conductive pad, thereby further hardening the encapsulant. The conductive bump is aligned with the point of the pre-solder when attaching the chip to the substrate.

### BACKGROUND OF THE INVENTION

1. Field of the Invention

The present invention relates to a flip chip assembly process, and more specifically to a process to form an encapsulant on a substrate for reducing silica filler contamination in a solder joint between a chip and the substrate.

2. Description of the Related Art

Due to the demand for high-density and high-power electronic packaging, flip chip technology has become widely used in many fields. As the name implies, flip is chip technology is characterized by flipping over a bare die for attachment to a substrate, through solder connections. However, as is known, significant strain is imposed on the solder connections during temperature cycling, when an organic material is used as the substrate. This strain results from the significant difference between the coefficient of thermal expansion between the organic substrate (14-17 ppm/° C.) and the silicon wafer (4 ppm/° C.). Consequently, the solder connections deteriorate over time at an accelerated rate.

Therefore, to reduce this connection strain and enhance reliability, encapsulant is usually filled into the space between the substrate and the chip. In this way, stress is dispersed to the encapsulant to alleviate stress on the connections. Thus, connection cracking is significantly reduced, and the life of the connections is prolonged. In addition, the encapsulant also prevents the transmission of leakage current caused by impurities between the solder connections. Statistical data shows that the reliability of the chip can be increased five to ten times when underfill encapsulation is utilized. Therefore, underfill encapsulation has become a highly desired process. However, there are problems that arise in connection with the various ways performing the underfilling process and the curing of the encapsulant.

Conventionally, most flip chip packages are encapsulated by dispensing a liquid encapsulant with low viscosity along the periphery of the chip. Capillary action, generated from the encapsulant in the narrow space (less than 100 μm) between the chip and the substrate, drives the encapsulant to fill the gap between the solder connections. Since filling is conducted by capillary action, it is very slow. This problem becomes even more serious as the chip size increases because filling time increases as the dimensions of the chip increase, thereby increasing the distance that the encapsulant must flow to fill the space.

For example, in a typical encapsulation operation, the filling takes several minutes to several tens of minutes for a 7 mm square chip depending on the filling temperature. Since capillary action alone is insufficient for larger underfill areas, as flow pressure cannot be effectively maintained, voids are easily formed in the encapsulant. Such voids require the flip chip package to be discarded from either popcorn effect, caused during subsequent thermal processes, or stress concentration, caused when the flip chip package is stressed. In addition, contamination on the surfaces to be bonded, such as flux residues, can reduce the wetting action and interfere with the flow of the encapsulant underfill, resulting in voiding, insufficient surface contact and degraded bonding strength. Consequently, reliability is adversely affected.

One solution to solve the aforementioned problems is to use a so-called no-flow underfill technique, which is performed in the following steps: (1) forming an encapsulant on a substrate; (2) attaching a chip to the substrate; (3) solder reflow. The encapsulant for the no-flow underfill technique is usually a low-viscosity and thermosetting epoxy, having a composition of flux to assist the solder reflow step. Processing time to encapsulate a flip chip package can be reduced by forming the encapsulant on the substrate prior to attaching the chip to the substrate. This also reduces the formation of voids within the encapsulant.

Unfortunately, the no-flow underfill technique leads to other problems, which negatively affect reliability and electrical performance of a flip chip package. In this regard, it is well known that silica fillers are usually added in an encapsulant material for a conventional package or flip-chip package to match the thermal expansion coefficients of a chip and the encapsulant. An encapsulant for the no-flow underfill technique also comprises silica fillers. When a chip is attached to a substrate, some of the silica fillers in the encapsulant are usually trapped between a conductive bump of the chip and a pad or pre-solder of the substrate. The silica fillers remain in a solder joint of the flip chip package when the conductive bump and pad/pre-solder are reflowed, negatively affecting reliability and electrical performance such as the electrical resistance of the solder joint of the flip chip package.

To illustrate a no-flow process of the prior art, reference is made to FIGS. 1A through 1F. FIGS. 1A through 1F are cross-sections illustrating how the silica fillers are trapped in a solder joint between a chip and substrate of a flip chip package during encapsulating steps of the flip chip package using the no-flow underfill technique.

In FIG. 1A, a substrate 120, having a solder mask 124 and a solder mask opening 123 formed on a top surface thereof is provided. A pad 121, also formed on the top surface of the substrate 120, is completely exposed by the solder mask opening 123, and an optional pre-solder 122 over the pad 121 is provided. Pad 121 is NSMD (non-solder mask design) type when pad 121 is completely exposed by the solder mask opening 123. Pre-solder 122 is optionally formed over the pad 121 as desired. Further, pre-solder 122 usually has an approximately flat surface.

In FIG. 1B, encapsulant 130 for the no-flow underfill technique is provided overlying substrate 120 by ways known in the art. As is also known, silica fillers 132 are randomly distributed in encapsulant 130.

In FIG. 1C, semiconductor chip 110, having a conductive bump 111 in an active surface, is attached to substrate 120. The conductive bump 111 is further attached to the pre-solder 122. As illustrated, there are silica fillers 132 above the pre-solder 122 and near the conductive bump 111.

In FIG. 1D, pre-solder 122 is reflowed to combine with the conductive bump 111 to form a solder joint 140. The conductive bump 111 is also reflowed when the conductive bump ill comprises a solder material. Encapsulant 130 for the no-flow underfill technique usually has a flux composition that lowers the surface tension between the melted pre-solder 122 and (melted) conductive bump 111 during reflow. Encapsulant 130 also hardens during reflow. Liquefaction of pre-solder 122 (and conductive bump 111) and combination of pre-solder 122 and conductive bump 111 are both quick, and the flat surface of pre-solder 122 makes it difficult to purge the silica fillers 132 above the pre-solder 122 and near the conductive bump 111. This process results in some silica fillers 132 below the conductive bump 111 and above the pre-solder 122 being trapped in solder joint 140, negatively affecting reliability and electrical performance of the solder joint 140.

In FIG. 1E, a situation in which substrate 120 comprises a pad 121′ of SMD (solder mask design), resulting from partial exposure by a solder opening 123′ of solder mask 124, is shown. A pre-solder 122′ is optionally formed over the pad 121 as desired. Further, pre-solder 122 usually has an approximately flat surface. When conductive bump 111 of semiconductor chip 110 is attached to the pad 121′, there are still some silica fillers 132 above the pre-solder 122′ and near the conductive bump 111.

In FIG. 1F, when pre-solder 122′ is reflowed to combine with the conductive bump 111 to form a solder joint 140′, some silica fillers are also trapped in the solder joint 140′ for the same reason described in connection with FIG. 1D.

U.S. Pat. No. 6,489,180 discloses another process for flip-chip packaging using a no-flow underfill technique. FIGS. 2A through 2G are cross-sections illustrating a flip-chip packaging process utilizing no-flow underfill technique that is similar to the one disclosed in U.S. Pat. No. 6,489,180.

In FIG. 2A, a substrate 220 for a flip chip package is provided. Substrate 220 has a solder mask 224 and bond pad 221 on a top surface thereof. Bond pad 221 is of NSMD type, wherein the bond pad 221 is completely exposed by solder mask opening 223.

In FIG. 2B, a conductive, sharp-pointed stud 222 is fabricated over the bond pad 221. The conductive, sharp-pointed stud 222 can be fabricated by a conventional wire-bonding method or by other methods as well. When fabricated by a conventional wire-bonding method, the sharp-point stud is formed from gold or aluminum.

In FIG. 2C, an encapsulant 230 is provided over the top surface of substrate 220, covering the bond pad 221 and conductive, sharp-pointed stud 222. The encapsulant may be provided by dispensing or other methods. The encapsulant 230 has silica fillers 232 randomly distributed in the encapsulant 230 to match the thermal expansion coefficients of a chip 210 in FIG. 2D and the encapsulant 230.

In FIG. 2D, a semiconductor chip 210 having a solder bump 211 is provided and attached to the substrate 220 in an upside-down (flip chip) manner with the solder bump 211 thereof aligned to the bond pad 221. The semiconductor chip 210 is then forcibly pressed against the substrate 220, such that the sharp-pointed stud 222 pierces the solder bump 211. As shown, silica fillers 232 are near the solder bump 211, conductive, sharp-pointed stud 222, and bond pad 221.

In FIG. 2E, a solder reflow step is performed to reflow the solder bump 211 over the bond pad 221 to electrically connect the semiconductor chip 210 and substrate 220, resulting from melted solder bump 211 flowing downward along the surface of the sharp-pointed stud 222 and bond pad 221. There are two principal factors affecting the flow speed of melted solder bump 211. One of the factors is capillarity of the melted solder bump 211 along the surface of the sharp-pointed stud 222 and bond pad 221, and the other is gravity on the melted solder bump 211. Unfortunately, the two forces acting on the melted solder bump 211 in substantially the same direction, accelerating the flow speed of melted solder bump 211. Silica fillers 232 between the solder mask 224 and bond pad 221, and between the solder bump 211 and bond pad 221 in FIG. 2D are therefore trapped in the solder bump 211 after the reflow step, negatively affecting the joint of the bond pad 221 and solder bump 211, resulting in decreased electrical performance and solder joint reliability of flip chip package 250a. Moreover, as shown, the conductive, sharp-pointed stud 222 is not reflowed and retains its former shape. The sharp point A still exists in the solder joint of flip chip package 250a, resulting in a point of stress concentration when solder bump 211 is stressed. Solder joint reliability of flip chip package 250a is therefore further negatively affected.

FIG. 2F illustrates a slightly different situation in which substrate 220 comprises a bond pad 221′ of SMD type resulting from partial exposure by a solder mask opening 223′ of solder mask 224. A conductive, sharp-pointed stud 222′ is fabricated over the bond pad 221′ by a conventional wire-bonding method or other method, using gold or aluminum when fabricated by the conventional wire-bonding method. When the semiconductor chip 210 is forcibly pressed against the substrate 220 so that the sharp-pointed stud 222′ pierces the solder bump 211, some silica fillers 232 are also near the solder bump 211, conductive, sharp-pointed stud 222, and bond pad 221.

As shown in FIG. 2G, the solder reflow step is performed to reflow the solder bump 211 over the bump pad 221′ to electrically connect the semiconductor chip 210 and substrate 220. During this step, some silica fillers 232 are trapped in the solder bump 211 after the reflow step, for the same reason described in FIG. 2E. This entrapment of silica fillers negatively affects the integrity of the joint between the bond pad 221′ and solder bump 211, resulting in decreased solder joint reliability of flip chip package 250b. Moreover, as shown, the conductive, sharp-pointed stud 222′ does not get reflowed and substantially retains its original shape, and the sharp point A′ still exists in the solder joint of flip chip package 250b, resulting in stress concentration when solder bump 211 is stressed. Solder joint reliability of the flip chip package 250b is therefore further negatively affected.

### SUMMARY OF THE INVENTION

Thus, the main object of the present invention is to provide a flip chip assembly process forming an underfill encapsulant and substrate used therewith allowing underfill to be finished without silica fillers trapped in the solder joint of the flip chip package, improving the solder joint reliability of the flip chip package.

Another object of the present invention is to provide a flip chip assembly process forming an underfill encapsulant and substrate used therewith that prevent stress concentration in the solder joint of the flip chip package when the solder joint is stressed to produce a flip chip package with higher reliability and longer life.

In order to achieve the above and other objects, the present invention provides a flip chip assembly process forming an underfill encapsulant. A broad aspect of the present invention is achieved from a process that include providing or forming a pre-solder over a pad of a substrate, wherein the pre-solder has a profile that tapers to a point. Further, after application of an underfill encapsulant (having silica fillers), the point of the pre-solder aligns with a conductive bump of a chip that is to be attached to the substrate assembly in a flip chip assembly. Thereafter, a reflow process causes a slow melt and reflow of the pre-solder into the aligned conductive bump. This slow reflow, coupled with the tapered shape of the pre-solder creates a unitary solder joint that is free (or substantially free) of silica fillers.

### BRIEF DESCRIPTION OF THE DRAWINGS

The present invention can be more fully understood by reading the subsequent detailed description in conjunction with the examples and references made to the accompanying drawings, wherein:

FIGS. 1A through 1F are cross-sections illustrating encapsulating steps of a flip chip package using a no-flow underfill technique in which silica fillers are trapped in a solder joint between a chip and substrate of a flip chip package during.

FIGS. 2A through 2G are cross-sections illustrating a flip-chip packaging process utilizing no-flow underfill technique similar to the one disclosed in U.S. Pat. No. 6,489,180.

FIGS. 3A through 3G are cross-sections and a top view illustrating a flip chip assembly process forming an underfill encapsulant in accordance with one embodiment of the present invention.

FIGS. 4A through 4C are cross-sections illustrating a flip chip assembly process forming an underfill encapsulant in accordance with a second embodiment of the present invention.

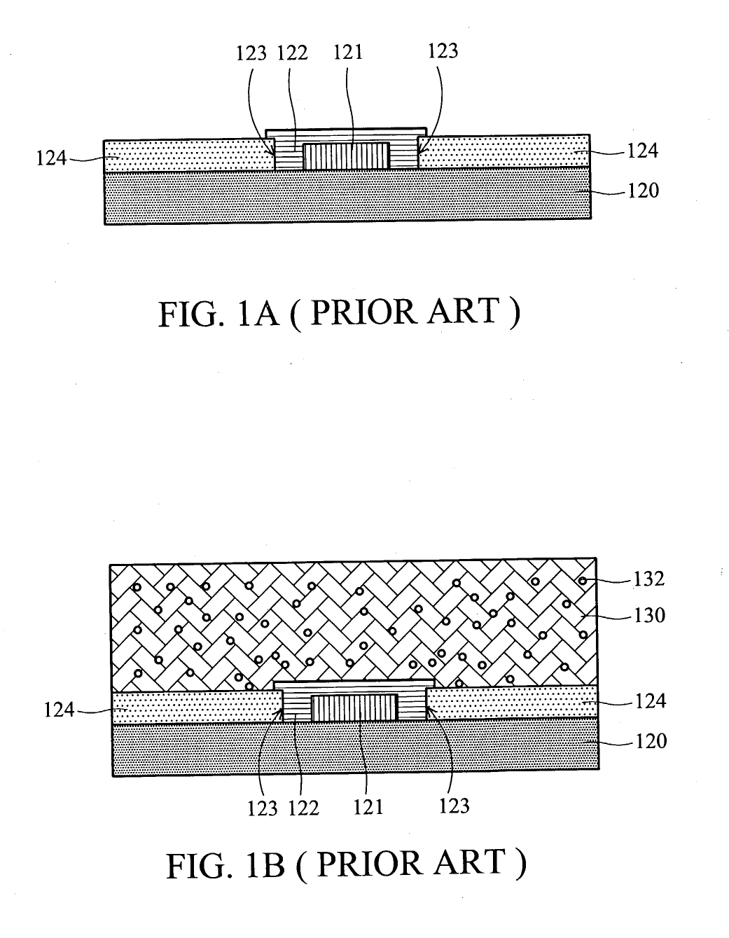

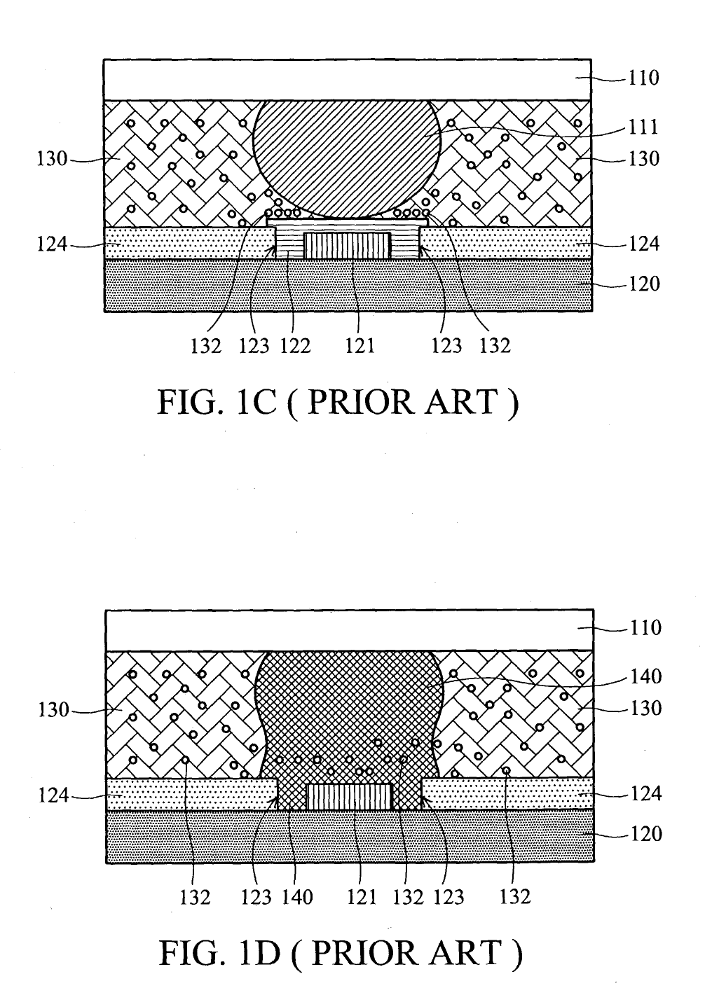

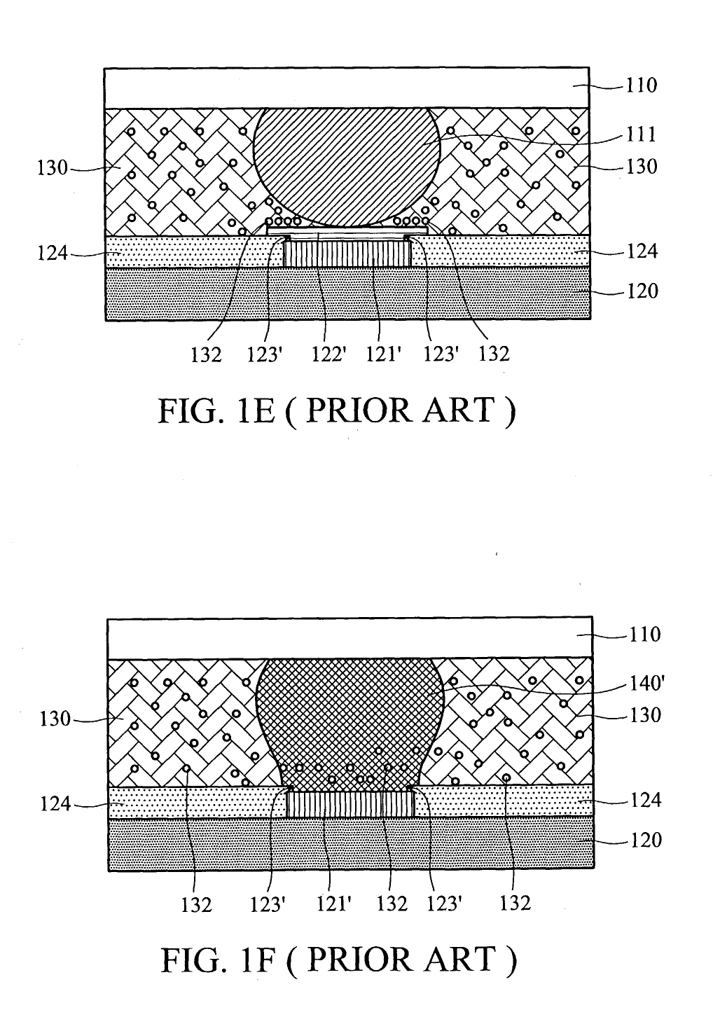

### DETAILED DESCRIPTION OF THE INVENTION

The following embodiments are intended to illustrate the invention more fully without limiting the scope of the claims, since numerous modifications and variations will be apparent to those skilled in this art.

First Embodiment

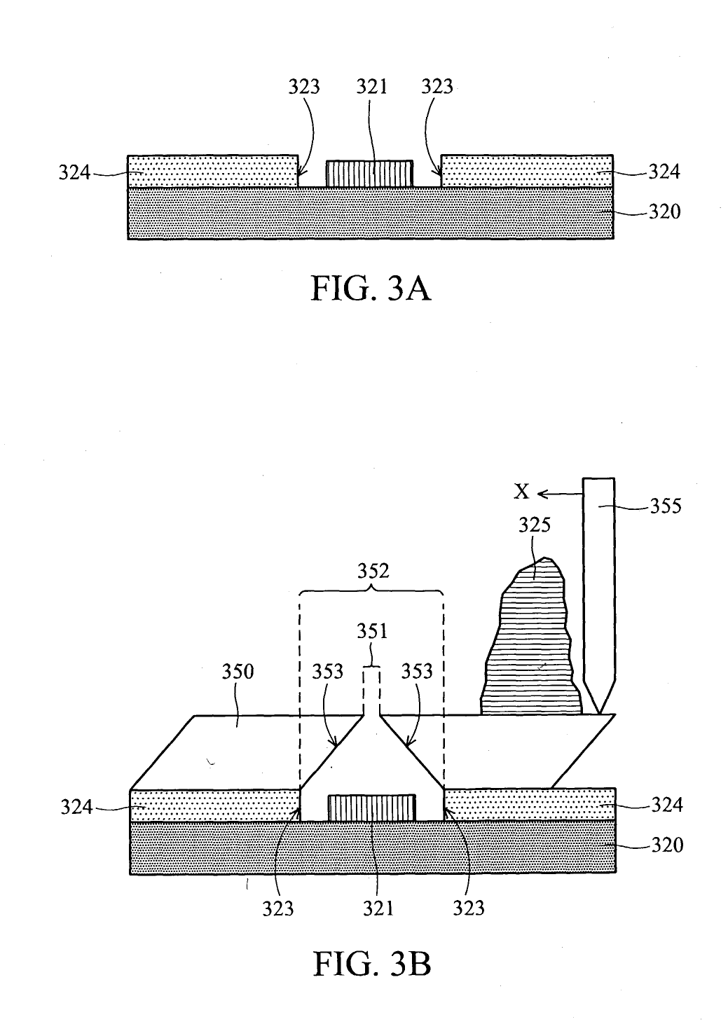

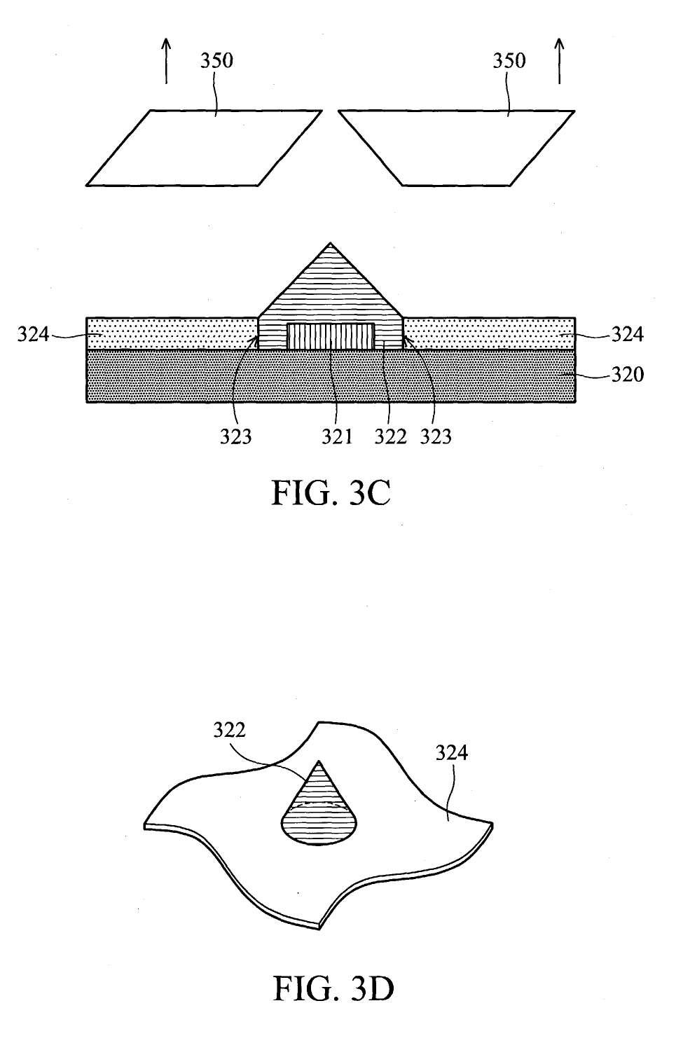

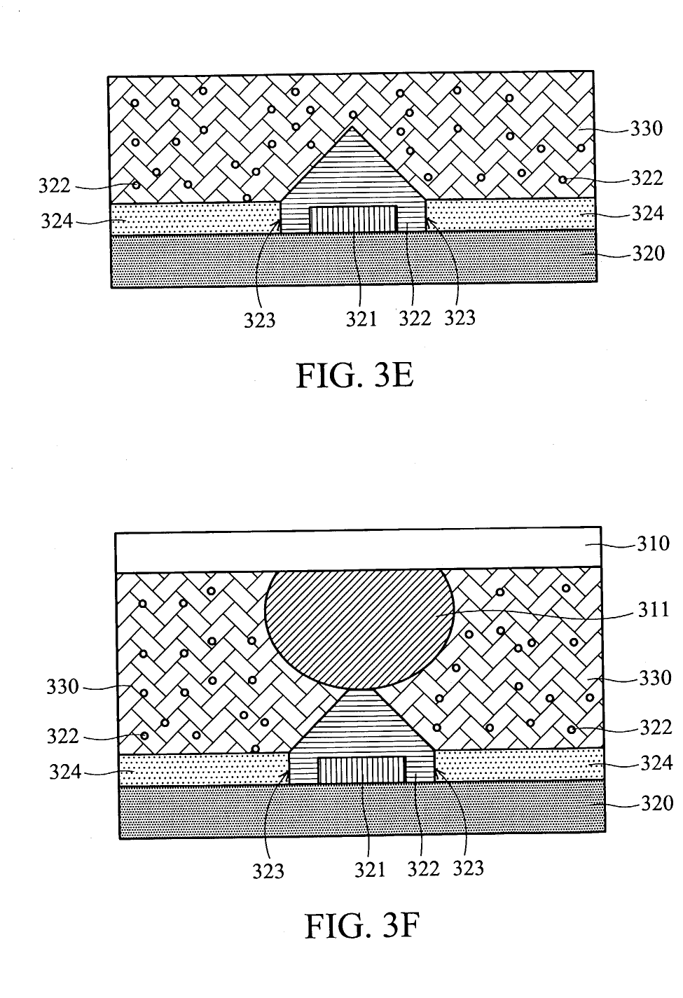

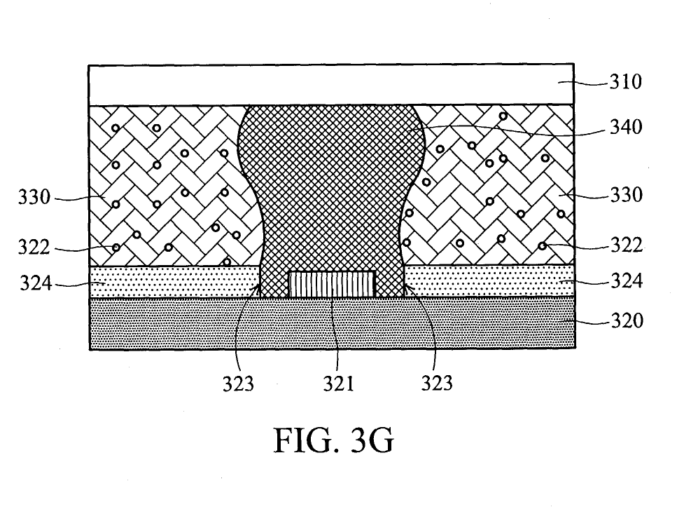

FIG. 3A through FIG. 3G show certain manufacturing steps of a flip chip assembly process forming an underfill encapsulant in accordance with one embodiment of the present invention. The present invention implements a flip chip assembly process forming an underfill encapsulant without silica filler contamination in the solder joint. The flip chip assembly formed by the present invention further prevents dangerous point or interface in the solder joint from inducing stress concentration when the solder joint is stressed, producing a flip chip package with better electrical performance, higher reliability, and longer life.

In FIG. 3A, a substrate 320, having a solder mask 324 and a solder mask opening 323 form on a top surface thereof is provided. A pad 321 is also provided and completely exposed within the solder mask opening 323. Pad 321 is NSMD. Pad 321 is conductive and usually comprises copper.

As shown in FIG. 3B, a stencil 350 defining an inverted funnel-shaped void is provided. The stencil 350 is used during intermediate processing steps of the underfill process by attachment to the substrate 320 in a position relation, such that a large (bottom) opening 352 is disposed adjacent the substrate 320 and a smaller (top) opening 351 is disposed away from the substrate. A substantially tapered, conical chamber 353 is formed between the large opening 352 and small opening 351. As shown in FIG. 3B, the large opening 352 is attach to substrate 320 and aligned with the pad 321.

As described below, the stencil 350 is used to form a pre-solder with a sharp top tip. The bottom opening 352 is preferably large enough to cover the solder mask opening 323 when stencil 350 is attached to substrate 320. Next in the processing, a solder paste 325, preferably comprising a solder material such as a tin-lead alloy or a lead-free, tin-based alloy, is provided overlying the pad 321. The solder paste 325 is applied over the pad 321 using a squeegee 355 sweeping solder paste 325 so as to cover the top of the substrate assembly and to force the solder paste 325 into the chamber 353 and fill the space defined by the inverted funnel-shaped stencil.

In FIG. 3C, solder paste 325 is reflowed to form a pre-solder 322 having a tapered shape ending in a sharp top tip overlying pad 321. Substrate 320 and stencil 350 are then separated. The stencil 350 is preferably made of stainless steel or metal coated with an unsolderable material to avoid being soldered during reflowing the solder paste 325. A preferred shape of pre-solder 322 is illustrated in perspective view of FIG. 3D, but is not restricted thereto. Indeed, as will be appreciated by persons skilled in the art, the improved stress and other benefits of the present invention will be realized through other pre-solder shapes as well.

In FIG. 3E, encapsulant 330 having silica fillers 332 for the no-flow underfill technique is formed or applied over the substrate 320 by such as dispensing or other known methods. As graphically depicted, silica fillers 332 are randomly distributed in encapsulant 330.

As shown in FIG. 3F, a semiconductor chip 310, comprising a conductive bump 311 in an active surface, is attached to substrate 320. Conductive bump 311 is further aligned and attached to the pre-solder 322. As graphically illustrated in FIG. 3F, due to the pressure applied from the conductive bump 311 against the pre-solder 322, the sharp tip of the pre-solder is somewhat flattened against the solder bump 311. As also illustrated, at this stage in the processing, there are some silica fillers 332 above the pre-solder 322 and near the conductive bump 311. The conductive bump 311 is preferably a solder material, gold, copper, gold coated by the solder material, or copper coated by the solder material. The solder material is preferably a tin-lead alloy or a lead-free, tin-based alloy.

In the processing step illustrated in FIG. 3G, pre-solder 322 is reflowed to combine with the conductive bump 311 to form a solder joint 340 resulting from melted pre-solder 322 flowing upward along the surface of the conductive bump 311. There are two principal factors affecting the flow speed of the melted pre-solder 322 during reflow. One of these factors is the capillarity of the melted pre-solder 322 along the surface of the conductive bump 311 and the other is gravity on the melted pre-solder 322. The two forces generally oppose each other (in direction) so as to reduce the flow speed of the melted pre-solder 322. The joint of pre-solder 322 and conductive bump 311 is therefore slower and the tapered profile of pre-solder 322 near contact with the conductive bump 311 with a slope resulting from the sharp tip makes it easier to purge the silica fillers 322 above the pre-solder 322 and near the conductive bump 311. This results in no (or virtually no) silica fillers 332 being trapped in solder joint 340, and thereby achieving the main object of the present invention.

The conductive bump 311 is also reflowed during reflowing of the pre-solder 321, when the conductive bump 311 comprises an appropriate solder material, such as a tin-lead alloy or a lead-free, tin-based alloy. When conductive bump 311 is also reflowed during reflowing pre-solder 322, the melted conductive bump 311 flows downward, in an opposing direction to the flowing of the melted pre-solder 322, thereby further slowing down the joint of pre-solder 322 and conductive bump 311. The combined action of the opposing and relatively slow flow of the pre-solder 321 and conductive bump 311, and tapered shape of the pre-solder acts to ensure that silica fillers removed or evacuated from the reflowed solder joint 340. This achieves a significant object of the present invention.

Encapsulant 330 for the no-flow underfill technique preferably has a flux composition that lowers the surface tension between the melted pre-solder 322 and (melted) conductive bump 311 during reflow. Encapsulant 330 also hardens during reflow. The reflow of the pre-solder 322 into the conductive bump creates a unified solder joint 340, wherein the sharp top tip (FIGS. 3C and 3D) of the pre-solder no longer exists. As a result, the solder joint 340 does not suffer from the stress concentration of prior art flip chip systems and processes.

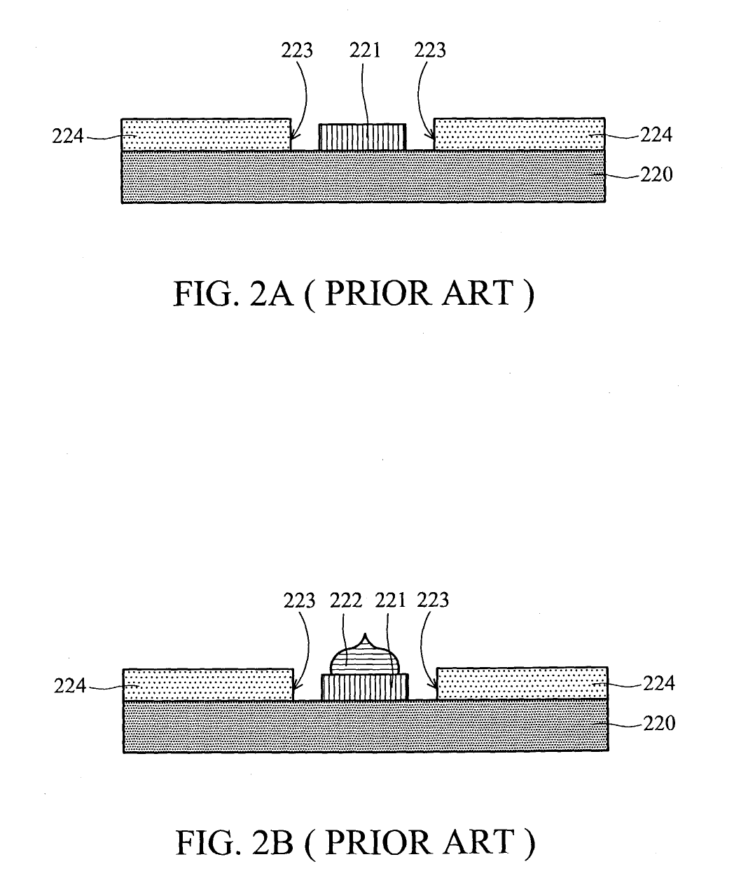

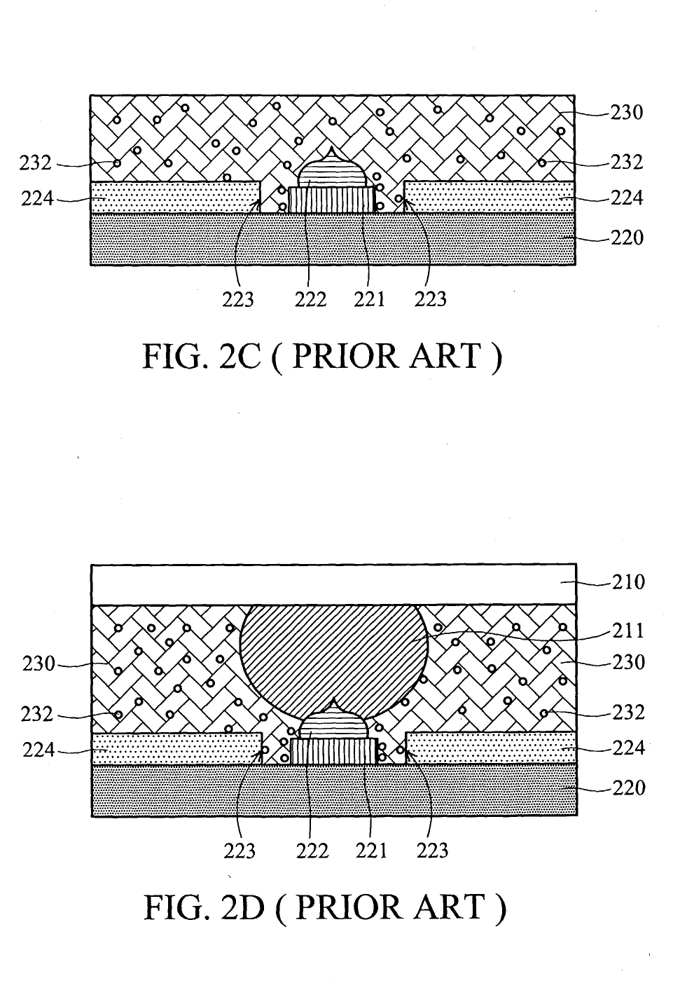

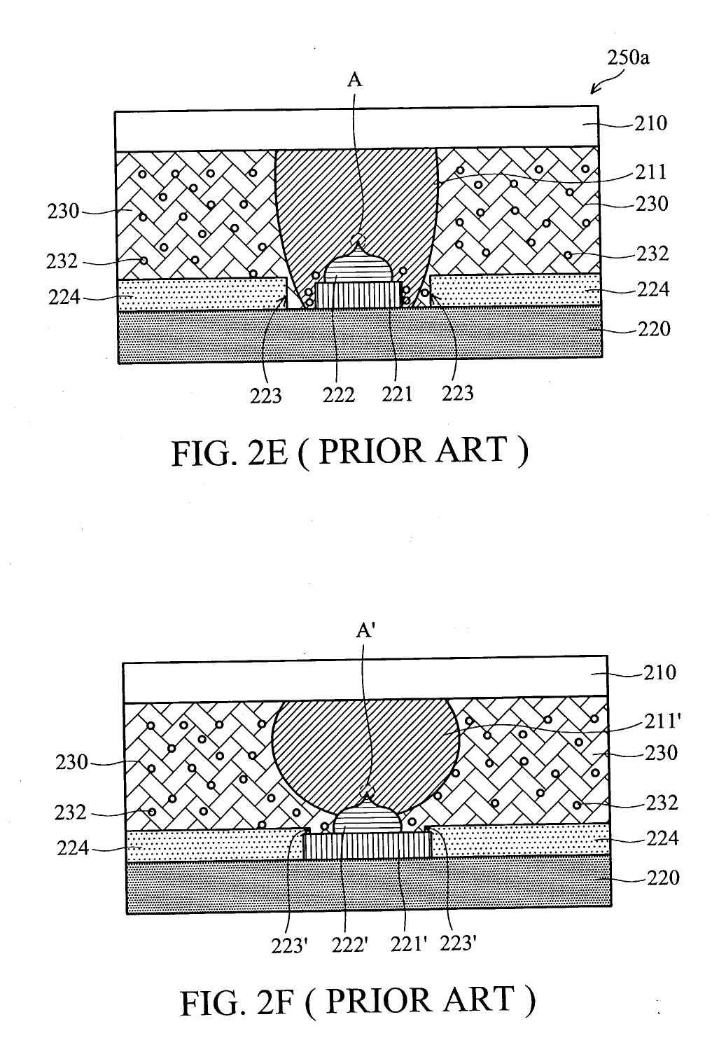

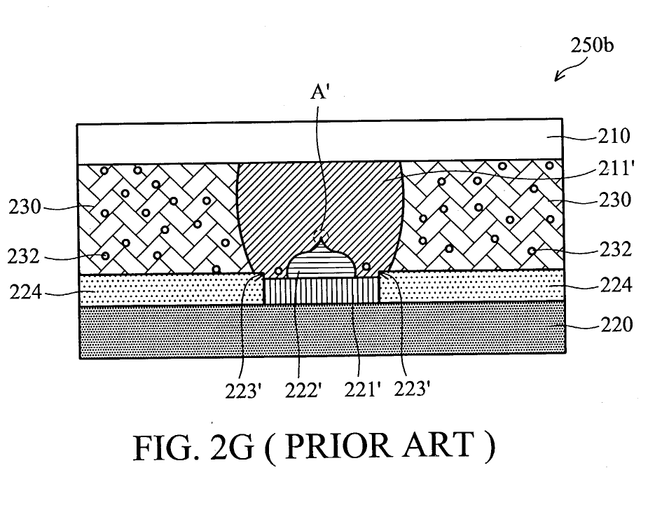

As described in FIG. 2B, the conductive, sharp-pointed stud 222 disclosed in U.S. Pat. No. 6,489,180 is formed from gold or aluminum when fabricated by a conventional wire-bonding method. The melting point of gold is approximately 1064.18° C. and that of aluminum is approximately 660.32° C. When the solder bump 211 in FIG. 2E is reflowed, reflowing temperature is usually not higher than 300° C. The conductive, sharp-pointed stud 222 is thus not reflowed or melted and retains its former shape during reflowing of solder bump 211 when fabricated by a conventional wire-bonding method. Therefore, the sharp point A still exists in the solder joint of flip chip package 250a, resulting in a point of stress concentration when solder bump 211 is stressed.

Second Embodiment

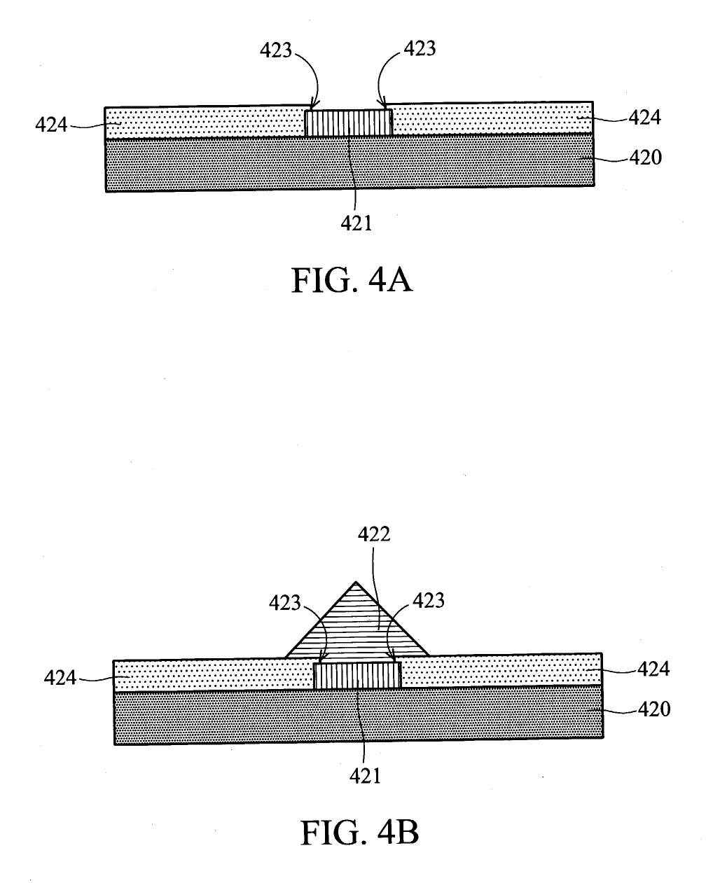

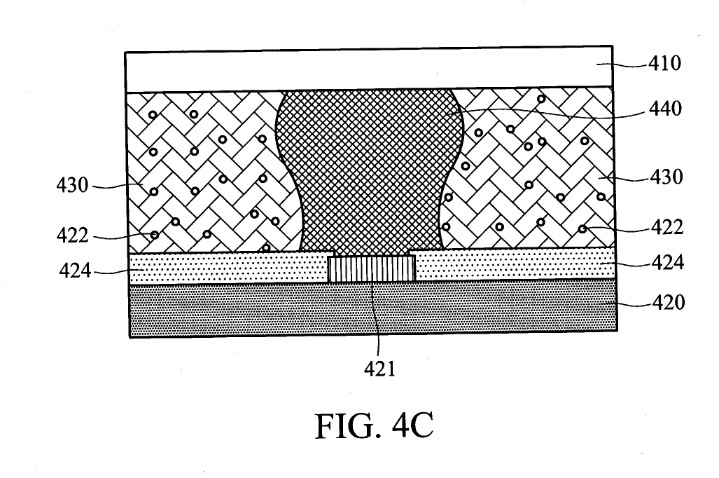

FIG. 4A through FIG. 4C illustrate manufacturing steps of a flip chip assembly process forming an underfill encapsulant in accordance with another embodiment of the present invention. The illustrated embodiment performs a flip chip assembly process with an underfill encapsulant without silica filler contamination in the resulting solder joint. Like the previously-described embodiment, this prevents undesired point or stress concentration point in the solder joint, thereby producing a flip chip package with better electrical performance, higher reliability, and longer life.

As shown in FIG. 4A, a substrate 420, having a solder mask 424 and a solder mask opening 423 on a top surface thereof. A pad 421, partially exposed by the solder mask opening 423, is also provided or formed on the top surface as well. Pad 421 is SMD, conductive, and preferably comprises copper.

In FIG. 4B, a pre-solder 422 having a sharp top tip is formed overlying pad 421 using the same procedure as in FIG. 3B and FIG. 3C. Pre-solder 422 usually comprises a solder material such as tin-lead alloy or lead-free, tin-based alloy.

As illustrated in FIG. 4C, encapsulant 430, having silica fillers 432 randomly distributed therein for the no-flow underfill technique, is formed overlying substrate 420 by dispensing or other known methods. Next, a semiconductor chip 410, comprising a conductive bump (not shown) in an active surface, is attached to substrate 420. The conductive bump of chip 410 is preferably a solder material, gold, copper, gold coated by the solder material, or copper coated by the solder material. The solder material is preferably a tin-lead alloy or a lead-free, tin-based alloy. Pre-solder 422 is then ref lowed to combine with the conductive bump of the chip 410 to form a solder joint 440 resulting from melted pre-solder 422 flowing upward along the surface of the conductive bump of chip 410. There are two principal factors affecting the flow of the melted pre-solder 422 during reflow. One of the factors is the capillarity of the melted pre-solder 422 along the surface of the conductive bump of chip 410. The other factor is the application of gravity on the melted pre-solder 422. The two forces act in substantially opposing directions, so as to reduce the flow speed of the melted pre-solder 422.

The formation of the resulting joint of pre-solder 422 and conductive bump of chip 410 is therefore slower. In addition, the tapered profile of pre-solder 422 near the contact point with the conductive bump of the chip 410 serves to alter the opposing reflow of the pre-solder and conductive bump to create a unitary solder joint that is free (or substantially free) of silica fillers 422.

Stated another way, the conductive bump of the chip 410 is also reflowed during reflowing pre-solder 421 when the conductive bump of the chip 410 comprises a solder material such as tin-lead alloy or lead-free, tin-based alloy. When conductive bump of the chip 410 is also reflowed during reflowing pre-solder 422, the melted conductive bump 411 flows downward, in a substantially opposing direction to the flow of the melted pre-solder 422, thereby further slowing down the joint of pre-solder 422 and conductive bump 411. The silica fillers 432 are therefore effectively evacuated or removed from the resulting solder joint 440, thereby achieving the main object of the present invention.

Encapsulant 430 for the no-flow underfill technique usually has a flux composition lowering the surface tension between the melted pre-solder 422 and (melted) conductive bump of the chip 410 during reflow. Encapsulant 430 also hardens during reflow. Because the pre-solder 422 has been reflowed, the sharp top tip no longer exists in solder joint 440. Consequently, the solder joint 440 does not suffer from stress concentration like prior art flip chip systems and processes.

As will be understood from the description provided herein, a broad aspect of the present invention is achieved from a process that include providing or forming a pre-solder over a pad of a substrate, wherein the pre-solder has a profile that tapers to a point. Further, after application of an underfill encapsulant (having silica fillers), the point of the pre-solder aligns with a conductive bump of a chip that is to be attached to the substrate assembly in a flip chip assembly. Thereafter, a reflow process causes a slow melt and reflow of the pre-solder into the aligned conductive bump. This slow reflow, coupled with the tapered shape of the pre-solder creates a unitary solder joint that is free (or substantially free) of silica fillers.

Although the present invention has been particularly shown and described above with reference to two specific embodiments, it is anticipated that alterations and modifications thereof will no doubt become apparent to those skilled in the art. It is therefore intended that the following claims be interpreted as covering all such alteration and modifications as fall within the true spirit and scope of the present invention.

1-14. (Canceled)

15. A substrate used in a flip chip assembly process for reducing silica filler contamination in a solder joint between a chip and the substrate, comprising:
a conductive pad overlying the substrate; and
a pre-solder that tapers to a point over the conductive pad and protrudes from the substrate.

16. The substrate as claimed in claim 15, wherein the conductive pad is of a NSMD type or a SMD type.

17. The substrate as claimed in claim 15, wherein the pre-solder comprises Sn—Pb alloy or Pb-free, Sn-based alloy.

18. An unsolderable stencil used in a flip chip assembly process for reducing silica filler contamination in a solder joint between a chip and the substrate, comprises an inverted funnel-shaped void, further comprising:
a top opening; and
a bottom opening larger than the top opening.

19. The stencil as claimed in claim 18, wherein the unsolderable stencil comprises stainless steel or a metallic material coated with an unsolderable material.
